(19) United States
(12) Patent Application Publication
(10) Pub. No.: US 2012/0267645 A1
(43) Pub. Date: Oct. 25, 2012

(54) LIGHT EMITTING DIODE MODULE PACKAGE STRUCTURE

(76) Inventors: Pao-Ting Lin, Zhudong Township (TW); Yu-Chu Tseng, Taipei City (TW)

(21) Appl. No.: 13/243,708

(22) Filed: Sep. 23, 2011

(30) Foreign Application Priority Data
Apr. 20, 2011 (TW) 100113700

(51) Int. Cl. H01L 25/075

(52) U.S. Cl. 257/88; 257/E25.02

(57) ABSTRACT

A light emitting diode (LED) module package structure is described. The LED module package structure includes a metal heat dissipating board, a plurality of light emitting diode chips fixed on the metal heat dissipating board, at least one chip-scale connector fixed on the metal heat dissipating board to electrically connect to the light emitting diode chip via a bonding wire. The chip-scale connector includes a sapphire substrate, a conductive metal layer and an insulation protruding member. The insulation protruding member divides the conductive metal layer into a plurality of conductive areas. In addition, the LED module package structure can further includes a chip-scale power connector fixed in the metal heat dissipating board to connect the chip-scale connector or the light emitting diode chip via the bonding wire.

### RELATED APPLICATIONS

This application claims priority to Taiwan Application Serial Number 100113700, filed Apr. 20, 2011, which is herein incorporated by reference.

### FIELD OF THE INVENTION

The present invention generally relates to a light emitting diode module package structure. More particularly, the invention relates to a light emitting diode module package structure having a chip-scale connector.

### BACKGROUND OF THE INVENTION

Since the science and technology of light-emitting diodes are progressive day by day, light modules constructed by the light-emitting diodes as light sources gradually replace the current incandescent lamps and fluorescent lamps. At present, a light-emitting diode light module is mainly constructed by soldering the light-emitting diode chips on a circuit board. The light-emitting diode chip can effectively light up an object by supplying electrical power to a p-type electrode and an n-type electrode of the light-emitting diode chip via a circuit board.

However, conventional light-emitting diode chips cannot convert most of input energy into optical energy, and the loss of the input energy is mostly in the form of heat loss. Therefore, the conversion efficiency of the conventional light-emitting diodes is worse. In addition, if the heat generated by the light-emitting diodes cannot be effectively expelled, the heat may further increase the junction temperature of the light-emitting diode chip. Hence, the heat not only reduces the conversion efficiency of the light-emitting diode chips, but also reduces the reliability of the light-emitting diode chips. Therefore, how to solve the thermal problem of the light-emitting diodes plays an important role for developing the light-emitting diodes.

Conventionally, some of the light-emitting diodes are soldered on a circuit board, and pins of the light-emitting diodes are electrically connected to a circuit layer of the circuit board with solder, and the circuit board is further connected to a metal heat dissipating block to facilitate cooling the LED diode chips.

In addition, some of the light-emitting diode chips are welded to a metal substrate to dissipate the heat generated by the light-emitting diode chips, and the light-emitting diode chips are further connected to a circuit board to provide the required power. At this moment, the high voltage-resistant capability of the circuit board is very important.

Therefore, the light-emitting diode module not only has to overcome the heat dissipation problem, but also the high voltage insulation problem, thus increasing the manufacture cost thereof.

### SUMMARY OF THE INVENTION

One objective of the present invention is to provide a light emitting diode module package structure which use chip-scale connectors to integrate a metal heat dissipating board with a die bonding process of a light emitting diode chip for improving the high voltage insulation capability of the light emitting diode module and meanwhile reducing the packaging cost of the light emitting diode module.

To achieve these and other advantages and in accordance with the objective of the present invention, as the embodiment broadly describes herein, the present invention provides a light emitting diode module package structure includes a metal heat dissipating board, a plurality of light emitting diode chips fixed on the metal heat dissipating board, and at least one chip-scale connector fixed on the metal heat dissipating board. The chip-scale connector and the light emitting diode chips are electrically connected via bonding wires.

The chip-scale connector includes a sapphire substrate and a first conductive metal layer. In addition, the chip-scale connector further includes an insulation protruding member used for dividing the first conductive metal layer into a plurality of conductive areas.

The chip-scale connector can further includes a second conductive metal layer, and the insulation protruding member divides the first conductive metal layer and the second conductive metal layer into a plurality of conductive areas. The first conductive metal layer and the second conductive metal layer are electrically insulated.

The chip-scale connector and the light emitting diode chips are fixed on the metal heat dissipating board in the same die bonding process. For example, the chip-scale connector and the plurality of light emitting diode chips can be fixed on the metal heat dissipating board by soldering. Alternatively, the chip-scale connector and the light emitting diode chips are fixed on the metal heat dissipating board with silver paste.

The light emitting diode module package structure can further include a chip-scale power connector fixed on the metal heat dissipating board. The chip-scale power connector, the chip-scale connector and the light emitting diode chips are electrically connected via bonding wires.

Accordingly, the light emitting diode module package structure according to the present invention can use the chip-scale connector to integrate with the die bonding process of the light emitting diode chip, and can use a bonding wire to connect the light emitting diode chip and the chip-scale connector. In addition, the light emitting diode module package structure according to the present invention can provide a high voltage insulation capability and reduce the manufacturing cost for packaging the light emitting diode module. Furthermore, the chip-scale connector can also increase diversity of the circuit configuration and reduce the length of gold wire to further reduce the light-emitting diode module packaging costs. The light emitting diode module package structure according to the present invention can further use the chip-scale power connector to conveniently connect to the light emitting diode chip and the chip-scale connector, thereby further simplifying the light emitting diode module package structure.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1 illustrates a light emitting diode module package structure according to an embodiment of the present invention;

FIG. 2 illustrates a light emitting diode module package structure according to another embodiment of the present invention;

FIG. 3 illustrates a chip-scale connector of the light emitting diode module package structure according to an embodiment of the present invention;

FIG. 4 illustrates a chip-scale connector of the light emitting diode module package structure according to another embodiment of the present invention; and

FIG. 5 illustrates a cross sectional view of a chip-scale power connector of the light emitting diode module package structure according to the present invention.

### DETAILED DESCRIPTION OF THE PREFERRED EMBODIMENT

The following description is of the best presently contemplated mode of carrying out the present invention. This description is not to be taken in a limiting sense but is made merely for the purpose of describing the general principles of the invention. The scope of the invention should be determined by referencing the appended claims.

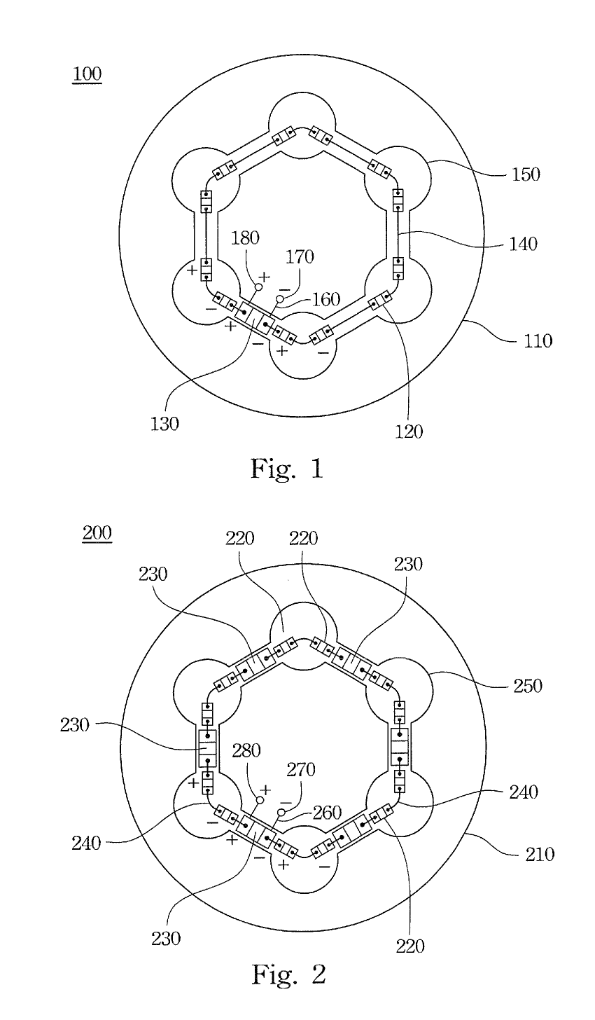

Referring to FIG. 1, FIG. 1 illustrates a light emitting diode module package structure according to an embodiment of the present invention. The light emitting diode module package structure 100 includes a metal heat dissipating board 110, a recessed area 150 formed on the metal heat dissipating board 110, a plurality of light emitting diode chips 120 which are fixed on the recessed area 150 and are electrically connected via bonding wires 140, a chip-scale connector 130 electrically connected to two ends of the light emitting diode chips 120, and a first chip-scale power connector 170 and a second chip-scale power connector 180 electrically connected to the chip-scale connector 130 via conducting wires 160.

The metal heat dissipating board 110 is made of a high thermal conductivity material, e.g. aluminum, copper, tungsten, nickel or the alloy thereof. The light emitting diode chip 120 is soldered on the metal heat dissipating board 110, or adhered on the metal heat dissipating board 110 with the silver paste.

In addition, the first chip-scale power connector 170 and the second chip-scale power connector 180, i.e. a negative power connector and a positive power connector, are electrically connected to the chip-scale connector 130 via the bonding wires or any other metal conducting wires.

Referring to FIG. 2, FIG. 2 illustrates a light emitting diode module package structure according to another embodiment of the present invention. The light emitting diode module package structure 200 includes a metal heat dissipating board 210 having a recessed area 250 formed thereon, a plurality of light emitting diode chips 220 and a plurality of chip-scale connectors 230 fixed in the recessed area 250. The light emitting diode chips 220 are electrically connected together via the bonding wires 240. The chip-scale connectors 230 can also be electrically connected to the light emitting diode chips 220 via the bonding wires 240. In addition, the chip-scale connectors 230 can be electrically connected to the first chip-scale power connector 270 and the second chip-scale power connector 280 via conducting wires 260.

The metal heat dissipating board 210 is preferably made of a high thermal conductivity material, e.g. aluminum, copper, tungsten, nickel or the alloy thereof. The light emitting diode chip 220 is soldered on the metal heat dissipating board 210, or glued on the metal heat dissipating board 210 with the silver paste. In addition, the chip-scale connector 230 is also soldered on the metal heat dissipating board 210, or glued on the metal heat dissipating board 210 with the silver paste.

The first chip-scale power connector 270 and the second chip-scale power connector 280, i.e. a negative power connector and a positive power connector, are electrically connected to the chip-scale connector 230 via the bonding wires or any other metal conducting wires.

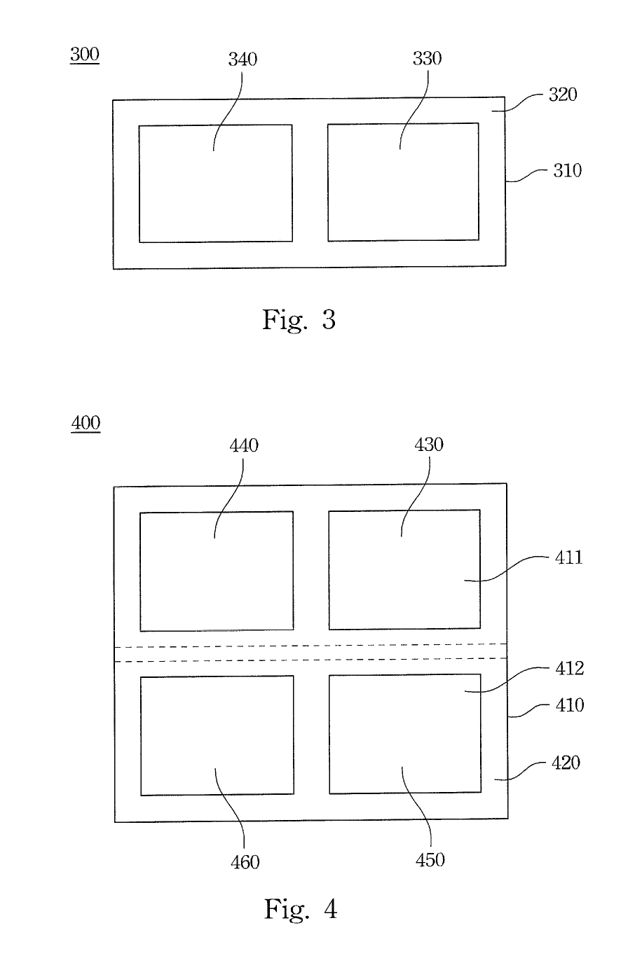

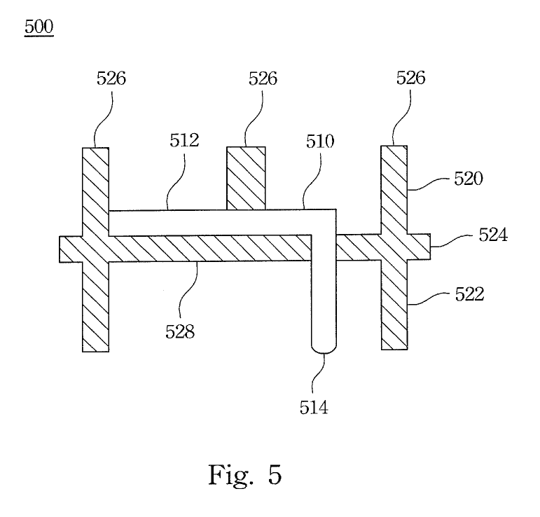

The chip-scale connectors of the light emitting diode module package structures shown in FIG. 1 and FIG. 2 are illustrated in the FIG. 3 and FIG. 4 respectively. In addition, an instance for implementing the chip-scale power connectors of the light emitting diode module package structures of FIG. 1 and FIG. 2 is illustrated in the FIG. 5.

Referring to FIGS. 3 and 4, FIG. 3 illustrates a chip-scale connector of the light emitting diode module package structure according to an embodiment of the present invention; and FIG. 4 illustrates a chip-scale connector of the light emitting diode module package structure according to another embodiment of the present invention.

The chip-scale connector 300 is preferably formed from a chip substrate 310 and an insulation protruding member 320. The chip substrate 310 can preferably use an insulation substrate, for example, a sapphire (Al₂O₃) layer, as the bottom layer of the light emitting diode chip, which can be directly fixed on a metal board, and withstand the same level of the dielectric withstanding voltage test as the light emitting diode chip. The voltage-resistant insulation capability of the chip substrate 310 is about 4000 voltages, and the chip-scale connector 300 can be easily fixed on a metal heat dissipating board with the same fixing method for fixing the light emitting diode chip on the metal heat dissipating board. Therefore, the chip-scale connector 300 and the light emitting diode chip can be simultaneously fixed on the metal heat dissipating board in the same manufacturing process, e.g. die bonding process, so that the manufacturing processes for manufacturing the light emitting diode module can effectively reduced.

The chip substrate 310 is preferably formed by a bottom insulating layer and a top conducting layer. The insulation body, e.g. the insulation protruding member 320, divides the conducing layer into a first conductive area 330 and a second conductive area 340. The insulation protruding member 320 can be formed on the chip substrate 310 by a plastic injection process or a semiconductor manufacturing process e.g. deposition process, etching process or coating process.

The chip-scale connector 300 having the insulation protruding member 320 can be conveniently used in the wire bond process. In the wire bond process, the chip-scale connector 300 and the light emitting diode chip can be electrically connected together via the bonding wire. The insulation protruding member 320 can effectively limit the melting metal during a soldering process, thereby improving the welding quality. The chip-scale connector 300 can effectively connect two light emitting diode chips so as to reduce the length of the bonding wire, e.g. golden wire, and the chip-scale connector 300 can effectively increase the diversity of the circuit configuration for connecting a plurality of light-emitting diode chips in series or parallel. In addition, each of the first conductive area 330 and the second conductive area 340 can be used for electrically connect one or more light emitting diode chips.

Further referring to FIG. 4, the chip-scale connector 400 preferably includes a chip substrate 410 and an insulation protruding member 420. The chip substrate 410 includes a bottom insulating layer, e.g. sapphire substrate, and further includes a first conductive layer 411 and a second conductive layer 412. The first conductive layer 411 and the second conductive layer 412 are electrically insolated. The insulation protruding member 420 can further divide the first conductive layer 411 into a first conductive area 430 and a second conductive area 440, and divide the second conductive layer 412 into a third conductive area 450 and a fourth conductive area 460.

Therefore, a single chip-scale connector 400 can effectively connect the light-emitting diode chips to the positive power source and the negative power source. Alternatively, the first conductive layer 411 and the second conductive layer 412 can also be designed to being electrically connected to each other. Therefore, the first conductive area 430, the second conductive area 440, the third conductive area 450 and the fourth conductive area 460 can be electrically connected to each other to effectively increase the area for wire bonding, thus connecting more light emitting diode chips in parallel or electrically connecting the other electronic elements.

Referring to FIG. 5, FIG. 5 illustrates a cross sectional view of a chip-scale power connector of the light emitting diode module package structure according to the present invention. The chip-scale power connector 500 can be inserted in the metal heat dissipating board as shown in the FIGS. 1 and 2 to electrically connect to an external power source. For example, the chip-scale power connector 500 can be the first chip-scale power connector 170 and the second chip-scale power connector 180 as shown in the FIG. 1, or the first chip-scale power connector 270 and the second chip-scale power connector 280 as shown in the FIG. 2.

The chip-scale power connector 500 includes a metal conducting member 510 and an insulation body 520. The metal conducting member 510 further includes at leas one conducting connection area 512 and at least one power terminal 514. The conducting connection area 512 and the power terminal 514 form an angle, preferably a right angle. The insulation body 520 includes a ring member 522, a flange 524, an insulation protruding member 526, and a supporting member 528. The ring member 522 can be inserted into an opening on the metal heat dissipating board, and the chip-scale power connector 500 can be snapped into the opening of the metal heat dissipating board with the flange 524 to avoid escaping from the other side of the opening. The insulation protruding member 526 can divide the metal conducting member 510 into at least one conducting connection area 512, and the supporting member 528 can support the metal conducting member 510. While using the chip-scale power connector 500, a corresponding connector is inserted into the chip-scale power connector 500 on the metal heat dissipating board to electrically connect with the power terminal 514. In addition, the bonding wire or the conducting wire can be conveniently soldered on the conducting connection area 512 to electrically connect the light emitting diode chip or the chip-scale connector, thus effectively simplifying the structure of the light emitting diode module. The chip-scale power connector 500 can be made in very small size, for example, similar to the size of the chip-scale connector or the light emitting diode chip, so as to be conveniently used in the light emitting diode module package structure.

Hence, the light emitting diode module package structure according to the present invention can use the chip-scale connector to integrate with the die bonding process of the light emitting diode chip, and use a bonding wire to connect the light emitting diode chip and the chip-scale connector. In addition, the light emitting diode module package structure according to the present invention can provide a high voltage-resistant insulation capability and reduce the manufacturing cost for packaging the light emitting diode module. Furthermore, the chip-scale connector can also increase diversity of the circuit configuration and reduce the length of gold wire for further reducing the light-emitting diode module packaging costs. The light emitting diode module package structure according to the present application can further use the chip-scale power connector to conveniently connect the light emitting diode chip and the chip-scale connector, thus further simplifying the light emitting diode module package structure.

As is understood by a person skilled in the art, the foregoing preferred embodiments of the present invention are illustrative of the present invention rather than limiting of the present invention. It is intended that various modifications and similar arrangements be included within the spirit and scope of the appended claims, the scope of which should be accorded the broadest interpretation so as to encompass all such modifications and similar structures.

What is claimed is:

1. A light emitting diode module package structure, comprising:
a metal heat dissipating board;
a plurality of light emitting diode chips fixed on the metal heat dissipating board; and
at least one chip-scale connector fixed on the metal heat dissipating board, wherein the chip-scale connector and the light emitting diode chips are electrically connected via bonding wires.

2. The light emitting diode module package structure of claim 1, wherein the chip-scale connector comprises a sapphire substrate and a first conductive metal layer.

3. The light emitting diode module package structure of claim 2, wherein the chip-scale connector further comprises an insulation protruding member used for dividing the first conductive metal layer into a plurality of conductive areas.

4. The light emitting diode module package structure of claim 3, wherein the chip-scale connector further comprises a second conductive metal layer, and the insulation protruding member used for dividing the first conductive metal layer and the second conductive metal layer into a plurality of conductive areas.

5. The light emitting diode module package structure of claim 4, wherein the first conductive metal layer and the second conductive metal layer are electrically insulated.

6. The light emitting diode module package structure of claim 1, wherein the chip-scale connector and the plurality of light emitting diode chips are fixed on the metal heat dissipating board in a die bonding process.

7. The light emitting diode module package structure of claim 1, wherein the chip-scale connector and the plurality of light emitting diode chips are fixed on the metal heat dissipating board by soldering.

8. The light emitting diode module package structure of claim 1, wherein the chip-scale connector and the plurality of light emitting diode chips are fixed on the metal heat dissipating board with silver paste.

9. The light emitting diode module package structure of claim 1, further comprises a chip-scale power connector fixed on the metal heat dissipating board.

10. The light emitting diode module package structure of claim 9, wherein the chip-scale power connector, the chip-scale connector and the light emitting diode chips are electrically connected via bonding wires.
